(19) United States
(12) Patent Application Publication
(10) Pub. No.: US 2026/0282541 A1
(43) Pub. Date: Sep. 17, 2026

(54) BONDED SOI WAFER PROCESS WITH ALIGNED FRONT AND BACK SIDE PATTERNS

(71) Applicant: Renesas Electronics America Inc., Milpitas, CA (US)

(72) Inventor: Robert Joseph KINZIG, Melbourne (FL)

(73) Assignee: Renesas Electronics America Inc., Milpitas, CA (US)

(21) Appl. No.: 19/078,873

(22) Filed: Mar. 13, 2025

(51) Int. Cl. H10D 86/01; H01L 21/762; H10D 30/01; H10D 62/00

(52) U.S. Cl. CPC H10D 86/01; H10D 30/021; H10D 62/01; H10P 90/1914; H10W 10/181

(57) ABSTRACT

A method of forming a semiconductor structure includes forming a first wafer with opposing first and second surfaces. A first pattern and a trench feature are formed on the first surface, with the trench feature extending toward the second surface. A first insulating layer is formed on the first surface of the first wafer lining sidewalls and bottom of the trench feature. An inside of the trench feature is filled with a polysilicon layer via the first insulating layer. The first wafer is bonded to a second wafer having opposed first and second surfaces via the first insulating layer, aligning their first surfaces. The bonded wafers are flipped, and a thinning process is conducted on the second surface of the first wafer forming a third surface. A second pattern is formed on the third surface aligned with the first pattern through the trench feature.

### BACKGROUND

The present disclosure generally relates to the field of semiconductor device fabrication, and more particularly to wafer-level bonding techniques.

Silicon-On-Insulator (SOI) technology has become a fundamental approach in semiconductor fabrication, offering improved device performance, reduced power consumption, and enhanced isolation compared to bulk silicon substrates. SOI wafers consist of a thin silicon device layer separated from a supporting handle wafer by a buried insulating layer, typically silicon dioxide (SiO₂). This structure provides advantages such as minimized parasitic capacitance, better thermal management, and increased scalability for advanced semiconductor applications.

Wafer bonding is a key technique for producing SOI wafers, enabling the integration of the thin silicon device layer onto an insulating substrate. Various bonding methods are employed, including direct bonding, in which two wafers are joined through molecular adhesion, and adhesive bonding, which utilizes an intermediate bonding layer. The process often includes high-temperature annealing steps to strengthen the bond, followed by thinning of the device wafer to achieve the desired silicon thickness. SOI wafer bonding is widely used in applications such as high-speed digital circuits, radio-frequency (RF) devices, and Micro-Electro-Mechanical Systems (MEMS), where improved electrical isolation and performance characteristics are essential.

Despite these advantages, the SOI wafer bonding process faces several challenges. Maintaining precise alignment between the device wafer and handle wafer is critical for ensuring proper electrical connections and structural integrity. Additionally, variations in thermal expansion, surface roughness, and bonding uniformity can introduce complexities that must be carefully managed during fabrication. As SOI technology continues to evolve, addressing these challenges remains essential for improving manufacturing efficiency and device performance.

### SUMMARY

According to an embodiment of the present disclosure, a method of forming a semiconductor structure includes forming a first wafer, the first wafer having a first surface and a second surface opposing the first surface, forming a first pattern on the first surface of the first wafer, forming a trench feature extending from the first surface towards the second surface of the first wafer, forming a first insulating layer on the first surface of the first wafer, the first insulating layer lining sidewalls and a bottom surface of the trench feature, filling an inside of the trench feature with a polysilicon layer via the first insulating layer, bonding the first wafer to a second wafer, the second wafer having a first surface and a second surface opposing the first surface, with the first wafer being bonded to the second wafer via the first insulating layer such that the first surface of the first wafer faces the first surface of the second wafer, flipping the bonded first wafer and second wafer, conducting a thinning process on the second surface of the first wafer, the thinning process forming a third surface of the first wafer, and forming a second pattern on the third surface of the first wafer, with the second pattern being aligned with the first pattern through the trench feature.

According to another embodiment of the present disclosure, a method of forming a semiconductor structure includes forming a first wafer having a first surface and a second surface opposite to the first surface, forming a first pattern on the first surface of the first wafer, forming one or more trench features extending from the first surface into the first wafer toward the second surface, forming a first insulating layer on the first surface, with the first insulating layer lining sidewalls and a bottom surface of the one or more trench features, filling an inside of the one or more trench features with a polysilicon layer via the first insulating layer, bonding the first wafer to a second wafer, the second wafer having a first surface and a second surface opposing the first surface, with the first wafer is bonded to the second wafer via the first insulating layer such that the first surface of the first wafer faces the first surface of the second wafer, flipping the bonded first wafer and second wafer, conducting a thinning process on the first wafer from the second surface, with the thinning process forming a third surface of the first wafer and exposing uppermost portions of the one or more trench features, the exposed uppermost portions of the one or more trench features serving as alignment markers on the second surface, and forming a second pattern on the third surface of the first wafer, with the second pattern being aligned with the first pattern using the alignment markers formed by the one or more trench features.

According to yet another embodiment of the present disclosure, a semiconductor structure includes a first wafer having a first surface and a second surface opposite to the first surface, and a second wafer bonded to the first surface of the first wafer, the first wafer including: a first pattern on the first surface of the first wafer, one or more trench features extending from the first surface into the first wafer towards the second surface, a first insulating layer positioned above the first surface, the first insulating layer lining sidewalls and a bottom surface of the one or more trench features, with the second wafer being bonded to the first surface of the first wafer via the first insulating layer and a second insulating layer disposed on a surface of the second layer, a polysilicon layer positioned within the one or more trench features above the first insulating layer, with uppermost portions of the polysilicon layer within the one or more trench features serving as alignment markers on the second surface, and a second pattern on the second surface of the first wafer, with the second pattern being aligned with the first pattern using the alignment markers.

### BRIEF DESCRIPTION OF THE DRAWINGS

The following detailed description, given by way of example and not intended to limit the embodiments described herein, will best be appreciated in conjunction with the accompanying drawings, in which:

FIG. 1 is a cross-sectional view of a semiconductor structure at an initial step during a wafer bonding process, according to an embodiment of the present disclosure;

FIG. 2 is a cross-sectional view of the semiconductor structure after forming a first oxide layer and a first sinker region within a device wafer, according to an embodiment of the present disclosure;

FIG. 3 is a cross-sectional view of the semiconductor structure after oxidizing first sinker region and patterning second sinker region within the device wafer, according to an embodiment of the present disclosure;

FIG. 4 is a cross-sectional view of the semiconductor structure after diffusion of first and second sinker regions and forming a first buried layer within the device wafer, according to an embodiment of the present disclosure;

FIG. 5 is a cross-sectional view of the semiconductor structure after forming a second buried layer within the device wafer, according to an embodiment of the present disclosure;

FIG. 6 is a cross-sectional view of the semiconductor structure after a thermal diffusion process and forming trench features, according to an embodiment of the present disclosure;

FIG. 7 is a cross-sectional view of the semiconductor structure after oxidizing trench features and forming a polysilicon layer within the trench features, according to an embodiment of the present disclosure;

FIG. 8 is a cross-sectional view of the semiconductor structure after bonding the device wafer to a handle wafer, according to an embodiment of the present disclosure;

FIG. 9 is a cross-sectional view of the semiconductor structure after conducting a thinning process on the device wafer, according to an embodiment of the present disclosure;

FIG. 10 is a cross-sectional view of the semiconductor structure after forming alignment marks, according to an embodiment of the present disclosure;

FIG. 11 is a cross-sectional view of the semiconductor structure after implanting and diffusing a well region, according to an embodiment of the present disclosure;

FIG. 12 is a cross-sectional view of the semiconductor structure after forming a hard mask layer and an insulating layer, according to an embodiment of the present disclosure;

FIG. 13 is a cross-sectional view of the semiconductor structure after forming a gate oxide and gate electrode, according to an embodiment of the present disclosure;

FIG. 14 is a cross-sectional view of the semiconductor structure after completion of a transistor region, according to an embodiment of the present disclosure; and

FIG. 15 is a flowchart depicting operational steps of a method for bonding SOI wafers with front and back-side patterns, according to an embodiment of the present disclosure.

The drawings are not necessarily to scale. The drawings are merely schematic representations, not intended to portray specific parameters of the embodiments in the present disclosure. The drawings are intended to depict typical embodiments of the present disclosure. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. The claimed structures and methods may, however, be embodied in many different forms and should not be construed as limited to the exemplary embodiments set forth herein. In the description, details of various conventional features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present disclosure, in the following detailed description, some processing steps or operations that may be ordinary in the art may have been combined together for presentation and for illustration purposes and in some instances may have not been described in detail. In other instances, some processing steps or operations that may be ordinary in the art may not be described at all. It should be understood that the following description is rather focused on the distinctive features or elements of various embodiments of the present disclosure.

In many bonded SOI wafer processes, an unpatterned device wafer is bonded to a handle wafer, followed by thinning and front-side patterning. This approach can limit design flexibility, as any buried layers must be formed after bonding, and require epitaxial (epi) growth. The use of an epi layer can introduce challenges such as autodoping effects, defects, and pattern distortions, making it difficult to fabricate high-precision devices. Additionally, processes that only pattern the front side do not easily allow for the integration of features on both sides of the device wafer, restricting opportunities to optimize electrical and structural characteristics.

To address these limitations, embodiments of the present disclosure provide a process that enables pattern formation on both the back side of the device wafer before bonding and the front side after thinning. In the proposed embodiments, alignment between front-side and back-side patterns can be achieved using trenches etched through the device layer.

Integrating layers and patterns on both sides of the device wafer enhances process flexibility and customization. This approach may allow for the incorporation of multiple buried layers with individually controlled doping profiles, using elements such as boron, phosphorus, arsenic, or antimony. The diffusion process can be tailored so that each buried layer reaches a specific depth within the silicon, enabling functionalities such as highly diffused sinkers or minimally diffused buried layers. The ability to form heavily doped buried layers or sinkers without requiring an epitaxial layer may help mitigate common challenges associated with epi processing, including autodoping effects, defects, and pattern shifts, while also streamlining the overall manufacturing process.

Embodiments by which bonded SOI wafers with front and back-side patterns can be formed are described in detail below by referring to the accompanying drawings in FIGS. 1-15.

FIG. 1 is a cross-sectional view of a semiconductor structure 100 at an initial step during a wafer bonding process, according to an embodiment of the present disclosure. At this step, semiconductor structure 100 includes a device wafer 102 illustrated before performing any processing steps. In an embodiment, the device wafer 102 can be a high-purity silicon wafer, selected based on its electrical and mechanical properties to ensure compatibility with subsequent fabrication steps. The device wafer 102 may serve as the foundation for defining buried layers, doped regions, and alignment structures before it is bonded to a handle wafer.

The device wafer 102 may have a first surface 104 and a second surface 106 opposite to the first surface 104. In an embodiment, the first surface 104 can be positioned on a first side 101 of the device wafer 102, while the second surface 106 can be positioned on a second side 103 of the device wafer 102. In an embodiment, the first side 101 is a front side of the device wafer 102 and the second side 103 is a back side of the device wafer 102. At this stage of the wafer bonding process, first surface 104 of the device wafer 102 may be unpatterned and free of oxide or deposited layers, allowing precise control over the initial processing steps. A thickness of the device wafer 102 may typically be chosen based on the final device specifications, considering factors such as dopant diffusion depths, mechanical stability, and post-bonding thinning requirements. The device wafer 102 may be prepared to undergo cleaning and oxidation steps to ensure a contamination-free surface, which is critical for achieving high-quality patterning and doping in later steps. In an embodiment, the device wafer 102 may have an initial thickness of approximately 675 mm.

As will be described in detail below, the first surface 104 of device wafer 102 may undergo patterning, etching, and doping to create first patterns, which may include, for example, sinker regions, buried layers and alignment marks. These features may play a crucial role in ensuring accurate front-to-back alignment once bonding occurs. Additionally, after bonding, similarly processes can be performed on the second surface 106 of device wafer 102 to form second patterns, which may include, for example, well regions, source and drain regions, and transistor regions. It should be noted that the terms “first pattern” and “second pattern” refer to features formed on the first surface 104 and second surface 106 of the device wafer 102, respectively. These patterns may include, but are not limited to, doped regions, conductive structures, and other device-related features.

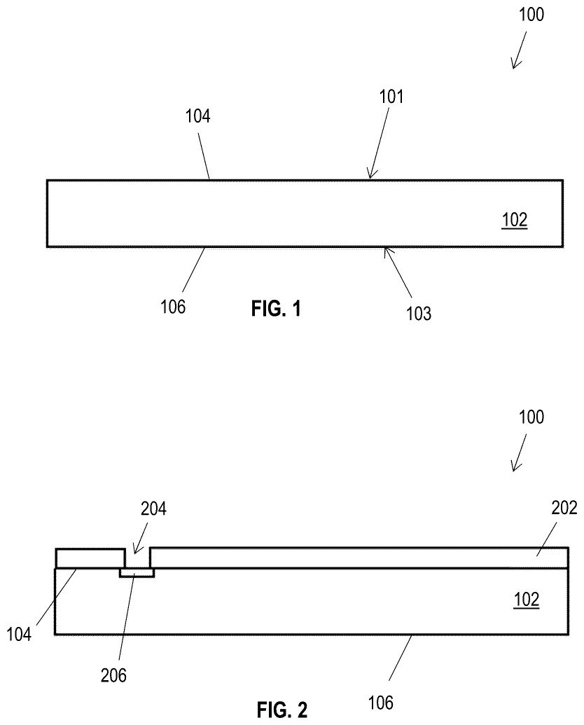

FIG. 2 is a cross-sectional view of the semiconductor structure 100 after forming a first oxide layer 202 and a first sinker region 206 within the device wafer 102, according to an embodiment of the present disclosure. The description of FIG. 2 may reference components depicted in FIG. 1.

In this embodiment, first oxide layer 202 is formed above the first surface 104 of the device wafer 102. The first oxide layer 202 can be thermally grown or deposited onto the first surface 104 of the device wafer 102. The first oxide layer 202 may serve as a masking layer, selectively protecting areas where doping should not occur while allowing precise formation of first sinker region 206. Generally, a thickness of the first oxide layer 202 may be chosen based on the doping process requirements, ensuring effective dopant confinement and preventing unwanted diffusion. In an embodiment, the first oxide layer 202 may be composed of silicon dioxide (SiO₂) and have a thickness varying from approximately 0.5 mm to approximately 1.2 mm.

After forming the first oxide layer 202, a photolithography process can be conducted on the device wafer 102. In this process a photoresist layer (not shown) is applied to a surface of the first oxide layer 202 and patterned using an exposure mask (not shown) that defines a location of the first sinker region 206. After development, exposed portions of the first oxide layer 202 can be etched, creating an opening 204 in the first oxide layer 202 where doping will be introduced to form first sinker region 206.

The process continues by conducting an ion implantation process or a thermal diffusion process on the device wafer 102 to form first sinker region 206. According to an embodiment, first sinker region 206 includes an N-type doped region. In embodiments in which dopant introduction is achieved by ion implantation, N-type dopant atoms (e.g., phosphorus or arsenic) are accelerated into silicon regions exposed by the opening 204 at controlled energy levels, embedding them at a precise depth. In embodiments in which dopant introduction is achieved by thermal diffusion, a dopant source is introduced, and high temperatures drive the diffusion of N-type atoms into the silicon through the opening 204 to form the first sinker region 206.

The first sinker region 206 may be designed to extend deep into the silicon-containing device wafer 102, ensuring effective electrical connectivity with subsequently formed buried layers. In one or more embodiments, after doping, device wafer 102 may undergo a high-temperature annealing process to activate N-type dopants, allowing them to fully integrate into the silicon lattice while repairing any crystal damage caused by implantation.

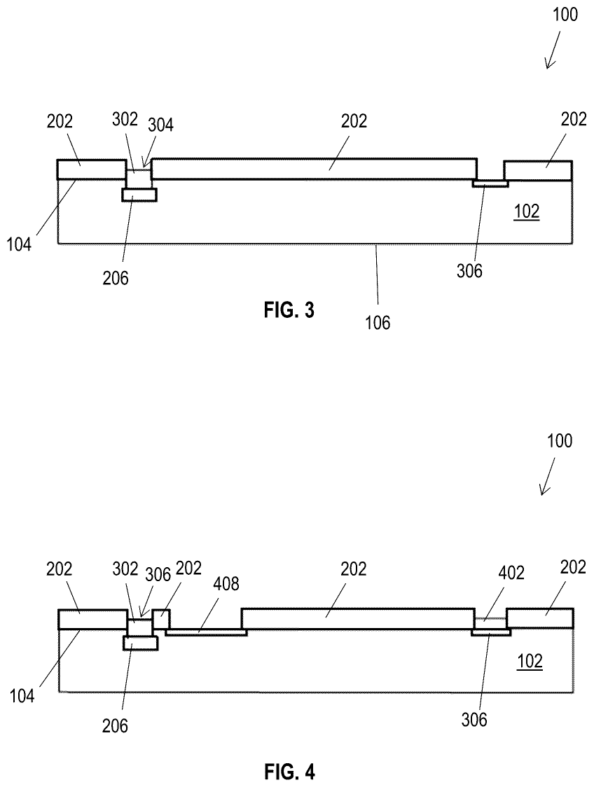

FIG. 3 is a cross-sectional view of the semiconductor structure 100 after oxidizing first sinker region 206 and patterning second sinker region 306 within the device wafer 102, according to an embodiment of the present disclosure. The description of FIG. 3 may reference components depicted in FIGS. 1-2.

In this embodiment, after the formation of first sinker region 206, the device wafer 102 may undergo another thermal oxidation process, where exposed silicon in the first sinker region 206 can be oxidized to form a protective oxide layer or second oxide layer 302 above the first sinker region 206. The second oxide layer 302 may prevent unwanted doping in the first sinker region 206 (i.e., N-type sinker region), provide electrical isolation, and establish a stable surface for subsequent processing steps. In the example of FIG. 3, the second oxide layer 302 may be composed of SiO₂ and have a thickness varying from approximately 0.5 mm to approximately 1.0 mm.

Formation of the second oxide layer 302 creates a step 304 in the first surface 104 of the device wafer 102. The step 304 may serve as a topographical alignment mark for subsequent photolithography steps, ensuring accurate positioning of future mask levels on this side (front-side) of the device wafer 102. A depth and profile of the step 304 may be controlled to maintain precision in alignment while preserving the integrity of the underlying silicon layer.

Following the oxidation process and alignment mark formation, a photolithography step can be performed on the device wafer 102 to define the second sinker region 306. In an embodiment, the second sinker region 306 is a P-type doped region. A photoresist layer (not shown) can be applied over the oxidized device wafer 102 and selectively exposed, using a mask (not shown), a location of the second sinker region 306. After development, the exposed oxide regions can be etched, revealing the underlying silicon where P-type dopants can be introduced to form the second sinker region 306.

With the P-type sinker pattern defined, the device wafer 102 may undergo P-type doping using ion implantation or thermal diffusion. P-type dopants such as boron (B) can be introduced into the exposed silicon regions to form the second sinker region 306. After implantation or diffusion, a high-temperature annealing process can be conducted on the device wafer 102 to activate the P-type dopants and allow them to fully integrate into the silicon lattice.

FIG. 4 is a cross-sectional view of the semiconductor structure 100 after diffusion of first and second sinker regions 206, 306 and forming a first buried layer 408 within the device wafer 102, according to an embodiment of the present disclosure. The description of FIG. 4 may reference components depicted in FIGS. 1-3.

In this step, the first sinker region 206 (N-type sinker) and second sinker region 306 (P-type sinker) undergo thermal diffusion, allowing the implanted dopants to migrate deeper into the device wafer 102 (i.e., the silicon substrate). This diffusion process may ensure that the first and second sinker regions 206, 306 extend sufficiently to establish electrical contact with buried layers while maintaining controlled doping profiles. Once diffusion is complete, an oxidation step is performed on the device wafer 102 to form a protective oxide layer or third oxide layer 402 above the second sinker region 306. This oxide layer serves as a mask for subsequent patterning steps while also providing electrical isolation and preventing unwanted dopant diffusion. Similar to the second oxide layer 302, the third oxide layer 402 may be composed of SiO₂ and have a thickness varying from approximately 0.1 mm to approximately 1.0 mm to prevent dopant diffusion. In some embodiments, the third oxide layer 402 may have a thickness varying from approximately 0.5 mm to approximately 1.0 mm to create a step in the silicon surface for another alignment mark (not shown).

Following the oxidation step, a photolithography process is conducted to define a pattern for the first buried layer 408. In an embodiment, the first buried layer 408 is an N-type buried layer (NBL). The process of forming the first buried layer 408 follows a similar approach to that used for the first and second sinker regions 206, 306. Specifically, N-type dopants, such as phosphorus or arsenic, are introduced through ion implantation or thermal diffusion into the exposed regions of the device wafer 102 to establish the first buried layer 408. In one or more embodiments, the first, second and third oxide layers 202, 302 and 402 may act as a mask for controlling where the N-type dopants can be introduced while protecting other regions from unwanted doping.

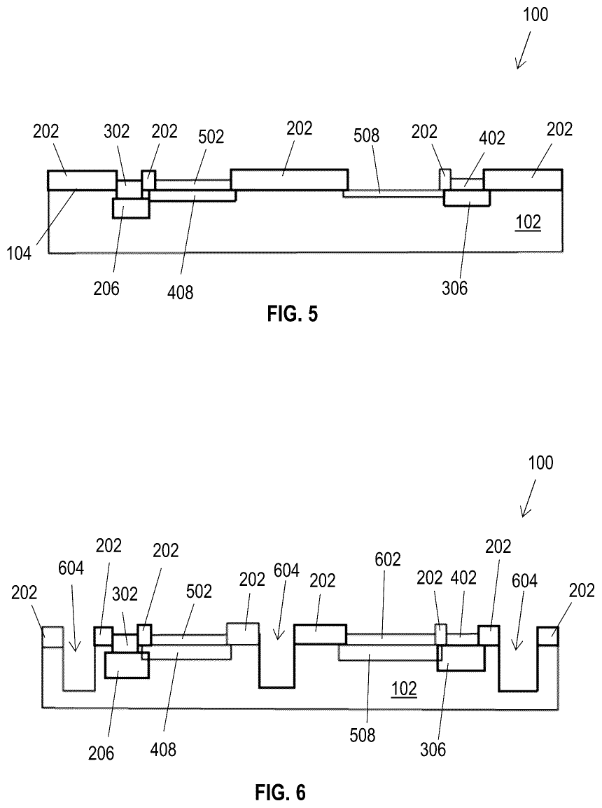

FIG. 5 is a cross-sectional view of the semiconductor structure 100 after forming a second buried layer 508 within the device wafer 102, according to an embodiment of the present disclosure. The description of FIG. 5 may reference components depicted in FIGS. 1-4.

In this step, first sinker region 206 and second sinker region 306 may undergo another thermal diffusion process that allows dopants to migrate deeper into the device wafer 102. This thermal diffusion process may ensure that the first and second sinker regions 206, 306 extend sufficiently to establish low-resistance electrical connections with buried layers. Simultaneously, the first buried layer 408 (i.e., NBL), which was previously implanted or pre-deposited, diffuses laterally and vertically into the device wafer 102, forming a conductive region beneath the active device layer. The diffusion conditions, such as temperature and duration, may be controlled to achieve the desired dopant concentration while preventing excessive lateral diffusion that could interfere with other regions.

Following the thermal diffusion process, an oxidation step may be conducted to grow a protective oxide layer or fourth oxide layer 502 above the first buried layer 408. The fourth oxide layer 502 may be formed using a process similar to that used for the first, second, and third oxide layers 202, 302, 402 and serves the same protective function during subsequent processing steps. Specifically, the fourth oxide layer 502 may help prevent further diffusion of dopants, maintain electrical isolation, and act as a masking layer for later patterning and implantation steps. In an embodiment, the fourth oxide layer 502 may be composed of SiO₂ and have a thickness varying from approximately 0.1 mm to approximately 1.0 mm to prevent unwanted dopant diffusion. In some embodiments, the fourth oxide layer 502 may have a thickness varying from approximately 0.5 mm to approximately 1.0 mm to create a step in the silicon surface for another alignment mark (not shown).

In an embodiment, after forming the fourth oxide layer 502, a photolithography process can be performed to define the second buried layer 508. In the depicted embodiment, the second buried layer 508 is a P-type buried layer (PBL). A photoresist layer (not shown) is applied to the device wafer 102 and selectively exposed through a mask (not shown) that defines the P-type buried layer regions. After exposure and development, the underlying silicon layer (i.e., device wafer 102) is exposed for P-type doping.

With the P-type buried layer pattern defined, P-type dopants such as boron can be introduced into the exposed silicon areas through ion implantation or thermal diffusion to form the second buried layer 508 (i.e., PBL). The diffusion process can be controlled to ensure the second buried layer 508 reaches the intended depth and lateral spread while maintaining alignment with the underlying first and second sinker regions 206, 306. Once the second buried layer 508 is formed, the device wafer 102 may undergo an annealing process to activate the dopants and optimize the electrical characteristics of the first and second buried layers 408, 508.

At the completion of this step, the device wafer 102 includes fully formed N-type and P-type buried layers (first and second buried layers 408, 508), which are aligned with their corresponding sinker region. After forming the required patterned layers or first patterns on the first surface 104 of device wafer 102, trench patterns can be formed and aligned with the first patterns on the first surface 104 prior to etching alignment trenches within device wafer 102, as will be described in detail below.

The first and second buried layers 408, 508 may establish electrical pathways and pattern features that will be utilized in the subsequent fabrication steps, including patterning and etching of trench features for additional electrical isolation and alignment.

FIG. 6 is a cross-sectional view of the semiconductor structure 100 after a thermal diffusion process and forming trench features 604, according to an embodiment of the present disclosure. The description of FIG. 6 may reference components depicted in FIGS. 1-5.

In this embodiment, the first sinker region 206, second sinker region 306, first buried layer 408 and second buried layer 508 undergo thermal diffusion to ensure that dopants reach their intended depth and lateral distribution within the device wafer 102. As mentioned above, the diffusion process may allow sinker regions to extend deeper into the wafer, ensuring that they establish low-resistance electrical connections with the first buried layer 408 and second buried layer 508. Similarly, the first buried layer 408 and second buried layer 508 may diffuse further to form well-defined conductive regions, maintaining alignment with the sinker regions. The diffusion conditions, including temperature and ambient gas composition, can be controlled to achieve optimal electrical characteristics while minimizing unwanted dopant spread.

It should be noted that a protective oxide layer or fifth oxide layer 602 may be formed above the second buried layer 508 using a process similar to the previous oxide growth steps. The fifth oxide layer 602 may serve as a mask for subsequent processing and help maintain the integrity of the underlying doped regions. In an embodiment, the fifth oxide layer 602 may be composed of SiO₂ and have a thickness varying from approximately 0.1 mm to approximately 1.0 mm.

Following the diffusion process, trench features 604 can be patterned and etched into the device wafer 102. A photolithography process is first performed to define the trench locations. A photoresist layer (not shown) is applied to the surface of the device wafer 102 and selectively exposed using a mask (not shown) that outlines the trench structures. After development, exposed regions of the device wafer 102 can be etched to form trench features 604. In an embodiment, trench etching can be conducted using, for example, a deep reactive ion etching (DRIE) or another anisotropic etching technique, ensuring precise vertical trench walls and controlled depths. In an embodiment, a depth of the trench features 604 may be at least several microns deeper than a final thickness of the device wafer 102. For example, when the final thickness of the device wafer 102 is approximately 7 mm, trench features 604 may be etched to a depth of approximately 10 mm.

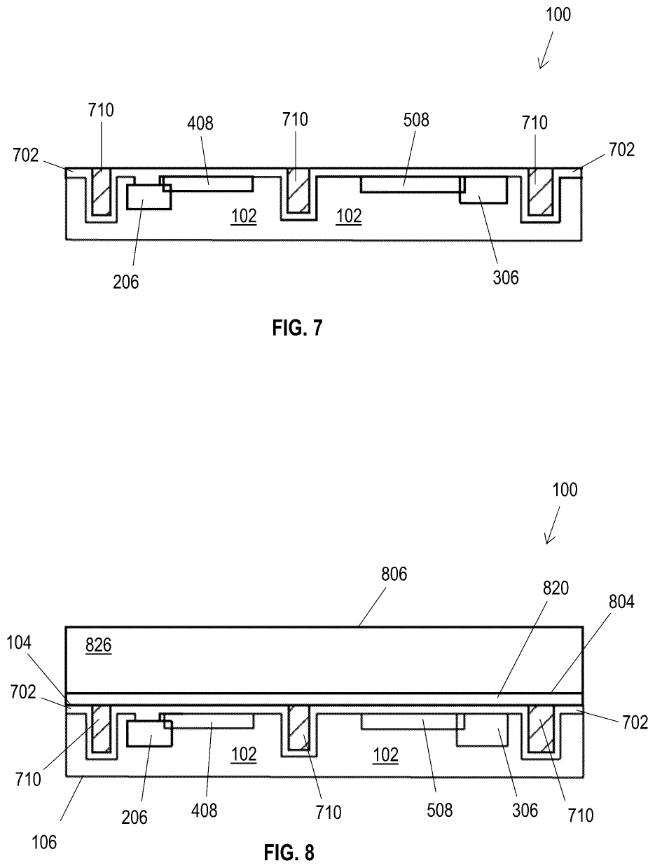

FIG. 7 is a cross-sectional view of the semiconductor structure 100 after oxidizing trench features 604, forming a polysilicon layer 710, and etching or polishing to remove the polysilicon not in the trenches, according to an embodiment of the present disclosure. The description of FIG. 7 may reference components depicted in FIGS. 1-6.

After forming trench features 604, an oxidation process can be performed on the semiconductor structure 100 to grow a thin oxide layer (hereinafter “oxide layer”) 702 along sidewalls and bottom surfaces of the trench features 604. The oxide layer 702 may be composed of SiO₂ and have a thickness varying from approximately 0.1 mm to approximately 0.3 mm. During the oxidation step, oxide layer 702 extends to and interfaces with previously formed oxide layers, including first, second, third, fourth, and fifth oxide layers 202, 302, 402, 502, 602, ensuring a continuous insulating structure across the semiconductor surface. Accordingly, for ease of illustration, these oxide layers will collectively be referred to as oxide layer 702. The oxidation process may help passivate the exposed silicon surfaces, reducing surface defects and preventing unwanted dopant diffusion. The oxide layer 702 may also enhance electrical isolation between adjacent regions, ensuring optimal device performance.

After the oxidation step, trench features 604 can be filled with a polysilicon (poly-Si) layer 710. In an embodiment, the polysilicon layer 710 can be deposited using a low-pressure chemical vapor deposition (LPCVD) process, ensuring uniform trench filling with high-purity material. Following the deposition of the polysilicon layer 710, an etch-back or chemical mechanical polishing (CMP) process can be performed on the semiconductor structure 100 to remove excess polysilicon material and achieve a flat, planarized surface, as depicted in FIG. 7. This step ensures that upper surfaces of the semiconductor structure 100 are leveled, allowing for precise patterning and processing in subsequent fabrication steps.

In an embodiment, the polysilicon-filled trench features 604 provide oxide isolation for devices and circuits within the device wafer 102, while also serving as alignment features that facilitates the precise alignment of back-side patterns with front-side patterns.

FIG. 8 is a cross-sectional view of the semiconductor structure 100 after bonding the device wafer 102 (first wafer) to a handle wafer 826 (second wafer), according to an embodiment of the present disclosure. The description of FIG. 8 may reference components depicted in FIGS. 1-7.

At this stage, the device wafer 102 is bonded to the handle wafer 826, which provides mechanical support and structural stability for subsequent processing steps. Prior to bonding, a handle wafer oxide layer 820 can be formed on a first surface 804 of the handle wafer 826 opposite to a second surface 806 of the handle wafer 826. The handle wafer oxide layer 820, along with the oxide layer 702 on the device wafer 102 may facilitate the bonding process by ensuring a strong and reliable interface between the device wafer 102 and the handle wafer 826. In an embodiment, the handle wafer oxide layer 820 is formed using a process similar to that of oxide layer 702. A thickness of the handle wafer oxide layer 820 may be approximately 2 mm, depending on the specific bonding and processing requirements.

In one or more embodiments, the bonding process can be performed using wafer direct bonding or adhesive bonding techniques. In the case of direct bonding, the wafers are precisely aligned and brought into contact, allowing intermolecular forces to create an initial bond. A subsequent annealing step at elevated temperatures strengthens the bond by promoting chemical reactions between the oxide surfaces, forming a stable silicon dioxide (SiO₂) interface.

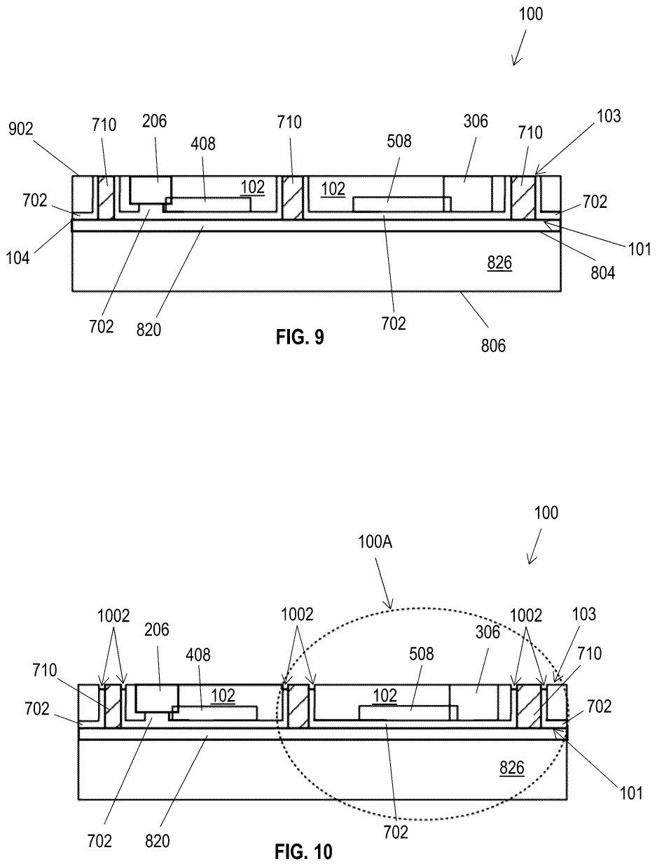

FIG. 9 is a cross-sectional view of the semiconductor structure 100 after conducting a thinning process on the device wafer 102, according to an embodiment of the present disclosure. The description of FIG. 8 may reference components depicted in FIGS. 1-8.

After bonding the device wafer 102 to the handle wafer 826, the wafer assembly is flipped, positioning the device wafer 102 on top of the handle wafer 826, as depicted in the figure. This reorientation may ensure that the thinning process is performed on the original back side (i.e., second side 103) of the device wafer 102, which will serve as the active device layer for subsequent processing.

Once flipped, the thinning process can be conducted on the back side (e.g., second side 103) of the device wafer 102 to achieve the required final device layer thickness. In an embodiment, the thinning process may begin with mechanical grinding, where a high-precision grinding tool removes excess silicon from the exposed surface of the device wafer 102. This initial grinding step may rapidly reduce the wafer thickness but may introduce surface roughness or subsurface damage. To refine the surface and achieve the desired final thickness, a chemical mechanical polishing (CMP) step is subsequently performed. CMP utilizes a combination of chemical etching and mechanical abrasion to create a highly planar surface with minimal defects.

During this step, the trench features 604 filled with the polysilicon layer 710 and the underlying semiconductor structures remain encapsulated, while the oxide layer 702 continues to provide structural integrity and bonding stability. At the completion of this step, the device wafer 102 may have reached its final thickness, making it ready for subsequent front-side processing steps, such as lithography, doping, and metallization. In an embodiment the final thickness of the device wafer 102 may be approximately 7 mm. The exposed surface of the device wafer 102 may also be referred to as a third surface 902, which corresponds to the second surface 106 after thinning and planarization.

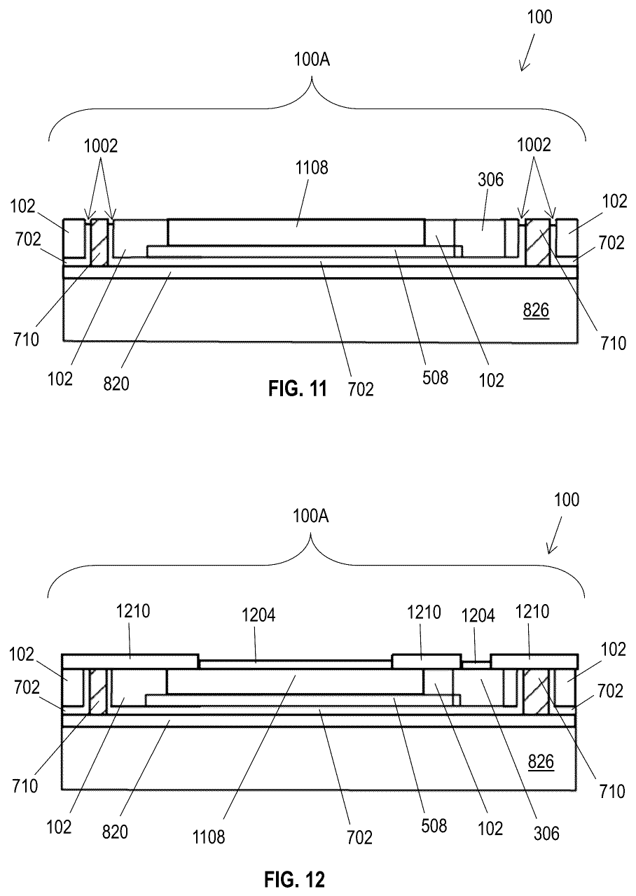

FIG. 10 is a cross-sectional view of the semiconductor structure 100 after forming alignment marks 1002, according to an embodiment of the present disclosure. The description of FIG. 10 may reference components depicted in FIGS. 1-9.

At this stage, an etch back process can be conducted on the oxide layer 702 to form the alignment marks 1002. For example, a hydrofluoric acid (HF) dip can be used to selectively etch the oxide layer 702, creating alignment marks 1002. Alignment marks 1002 include a trench or recess formed within the oxide layer 702 that can be used for precise patterning during subsequent top-side processing steps. The selective etch process used to form alignment marks 1002 may ensure that the trench features 604 filled with the polysilicon layer 710 maintain their structural integrity while exposing key alignment features that aid in the accurate positioning of future layers. In an embodiment, a depth of the alignment marks 1002 may be controlled to achieve optimal contrast for alignment. In an exemplary embodiment, the depth of the alignment marks 1002 may be approximately 0.25 mm.

It should be noted that after bonding the device wafer 102 to the handle wafer 826 and flipping it, the thinning process exposes portions of the polysilicon layer 710 filling trench features 604 at the second side 103 of the device wafer 102. The exposed trench features 604 including alignment marks 1002 may serve as visible or detectable alignment markers, enabling alignment tools to precisely position back-side patterns relative to front-side patterns. By directly linking the front-side and back-side features, this alignment method eliminates pattern shift that may result in non-functional devices or circuits.

For ease of illustration, without intent of limitation, the following embodiments will be described with reference to a region 100A of the device wafer 102. It may be understood that similar processes are conducted in remaining areas of the device wafer 102.

FIG. 11 is a cross-sectional view of region 100A of the semiconductor structure 100 after implanting and diffusing a well region 1108, according to an embodiment of the present disclosure. The description of FIG. 11 may reference components depicted in FIGS. 1-10.

In the depicted embodiment, well region 1108 is formed above the second buried layer 508 (PBL) using ion implantation and thermal diffusion. In an embodiment, the well region 1108 can be a P-type doped well region configured to provide a localized region of P-type doping within the region 100A of device wafer 102. Well region 1108 may serve as a critical structure for defining active device regions.

The process of forming the well region 1108 starts with ion implantation. In embodiments in which the well region 1108 is a P-type well region, boron (B) or other P-type dopants are introduced into exposed silicon regions using a high-energy ion beam. The implantation dose and energy can be controlled to achieve the desired doping concentration and depth. This ensures that the well region 1108 extends sufficiently into the silicon to form a stable and well-defined electrical region.

Following implantation, a thermal diffusion process can be performed on the device wafer 102, where high-temperature annealing allows the implanted dopants to migrate deeper into the silicon lattice. The thermal diffusion process may provide a gradual dopant profile in the well region 1108, reducing abrupt junction transitions and improving device performance. In an embodiment, well region 1108 is aligned with the second buried layer 508 (PBL). This alignment may maintain proper electrical continuity and isolation from adjacent structures.

FIG. 12 is a cross-sectional view of the region 100A of semiconductor structure 100 after forming a hard mask layer 1204 and an insulating layer 1210, according to an embodiment of the present disclosure. The description of FIG. 12 may reference components depicted in FIGS. 1-11.

At this stage, multiple dielectric layers are formed to define isolation regions and prepare for subsequent device processing. For instance, in the depicted embodiment, a hard mask layer 1204 can be deposited and patterned above upper surfaces of the semiconductor structure 100. In an embodiment, the hard mask layer 1204 can be a silicon nitride (Si₃N₄) layer deposited using a chemical vapor deposition (CVD) process. A thickness of the hard mask layer 1204 may be approximately 0.2 mm. In an embodiment, the hard mask layer 1204 may function as a mask to prevent oxide growth in selected regions while allowing it in others. Patterning of the hard mask layer 1204 can be achieved through photolithography and etching, where a photoresist mask (not shown) defines the areas where the hard mask layer 1204 is to remain, and the unprotected regions are selectively removed.

After forming the hard mask layer 1204, a thermal oxidation process can be performed on the semiconductor structure 100 to form an insulating layer 1210 in the exposed silicon regions of device wafer 102. In one or more embodiments, the insulating layer 1210, which may also be referred to as field oxide, serves as an isolation barrier for preventing electrical interference between adjacent active devices. A thickness of the insulating layer 1210 can be controlled to achieve optimal electrical isolation while maintaining compatibility with later processing steps. In an exemplary embodiment, the thickness of the insulating layer 1210 may be approximately 0.6 mm.

Although not depicted in the figures, in some embodiments, a thin pad oxide layer can be grown on the surface of the device wafer 102 prior to forming the hard mask layer 1204. This thin pad oxide layer may serve as a stress buffer between the underlying silicon and the hard mask layer 1204.

FIG. 13 is a cross-sectional view of the semiconductor structure 100 after forming a gate oxide 1308 and gate electrode 1320, according to an embodiment of the present disclosure. The description of FIG. 13 may reference components depicted in FIGS. 1-12.

In this embodiment, the hard mask layer 1204 (and thin pad oxide layer, if formed) can be removed to expose active regions of the device wafer 102 in preparation for transistor formation. The hard mask layer 1204 can be selectively remove using a wet etch process, such as phosphoric acid (H₃PO₄). In embodiments in which the thin pad oxide layer is formed, a hydrofluoric acid (HF) can be used for oxide removal. Removal of the hard mask layer 1204 exposes the active silicon regions while preserving the insulating layer 1210.

Following the removal of the hard mask layer 1204, gate oxide 1308 can be grown, and a polysilicon layer is deposited and patterned to define gate electrode 1320. The gate oxide 1308 is grown over the exposed silicon regions through thermal oxidation. The gate oxide 1308 may serve as an insulating layer between the gate electrode 1320 and underlying channel region (not shown), ensuring proper electrical operation. In an embodiment, a thickness of the gate oxide 1308 may vary between approximately 0.01 mm and approximately 0.05 mm.

After forming gate oxide 1308, a polysilicon layer can be deposited over the entire wafer surface using, for example, low-pressure chemical vapor deposition (LPCVD). A photolithography step is then performed to define the gate electrode 1320, followed by etching to remove excess polysilicon, leaving behind the patterned polysilicon gate electrode 1320 in the active regions of device wafer 102, as illustrated in FIG. 13.

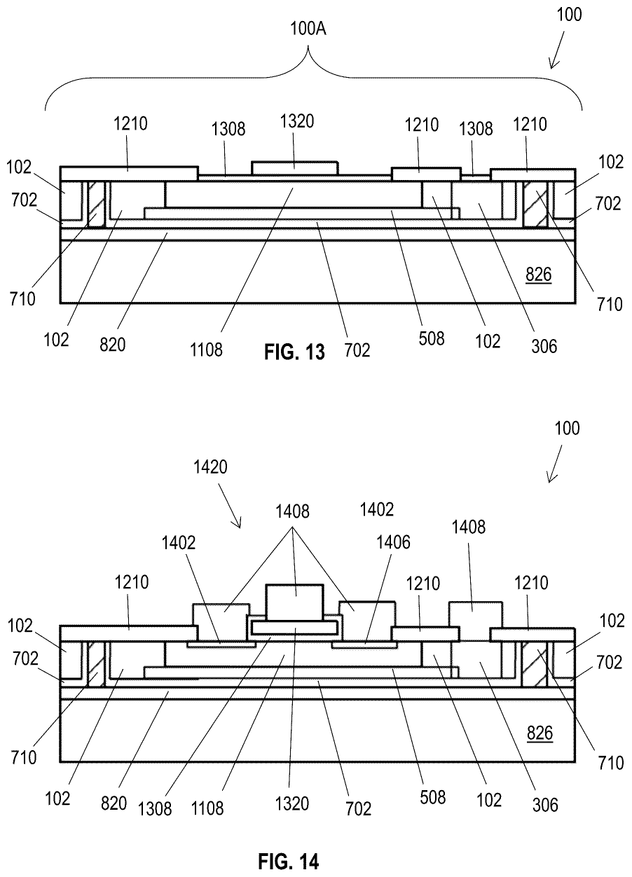

FIG. 14 is a cross-sectional view of the region 100A of semiconductor structure 100 after completion of a transistor region 1420, according to an embodiment of the present disclosure. The description of FIG. 14 may reference components depicted in FIGS. 1-13.

In this embodiment, an oxidation process is performed on the semiconductor structure 100 to oxidize the (polysilicon) gate electrode 1320. During the oxidation process, a thin oxide layer can be formed on the polysilicon surface. For easy of illustration the thin oxide layer formed around the gate electrode 1320 is collectively depicted with the gate oxide 1308. This oxidation step may improve the stability of the gate electrode 1320, provides passivation, and helps reduce gate-to-contact leakage in subsequent metallization steps.

Following the oxidation process, source and drain doping can be performed to introduce highly conductive regions into the well region 1108. In an embodiment, this step may involve implanting N-type dopants (such as phosphorus or arsenic) into the exposed silicon regions adjacent to the gate electrode 1320 to form source region 1402 and drain region 1406. The doping parameters, including dose and energy, can be controlled to ensure proper junction depth and electrical characteristics, optimizing the transistor's performance.

After forming source and drain regions 1402, 1406, a contact etching process can be conducted to create openings (not shown) through insulating layers, exposing source, drain and body contact regions. A photolithography step defines the contact locations, followed by anisotropic etching, which ensures that the contact openings extend precisely to the underlying silicon. The etched contacts allow direct electrical connections to the transistor's active regions.

Finally, a metal layer 1408 is deposited over the surface of device wafer 102 using, for example, physical vapor deposition (PVD) or sputtering techniques. The metal layer 1408 serves as the electrical interconnects for the transistor. A photolithography and etching process is then performed to pattern the metal layer 1408 such that it connects the source region 1402, the drain region 1406, the gate electrode 1320, and second sinker region 306 (body region) as required for circuit functionality. The metal layer 1408 establishes low-resistance pathways for external connections, completing fabrication of the transistor region 1420.

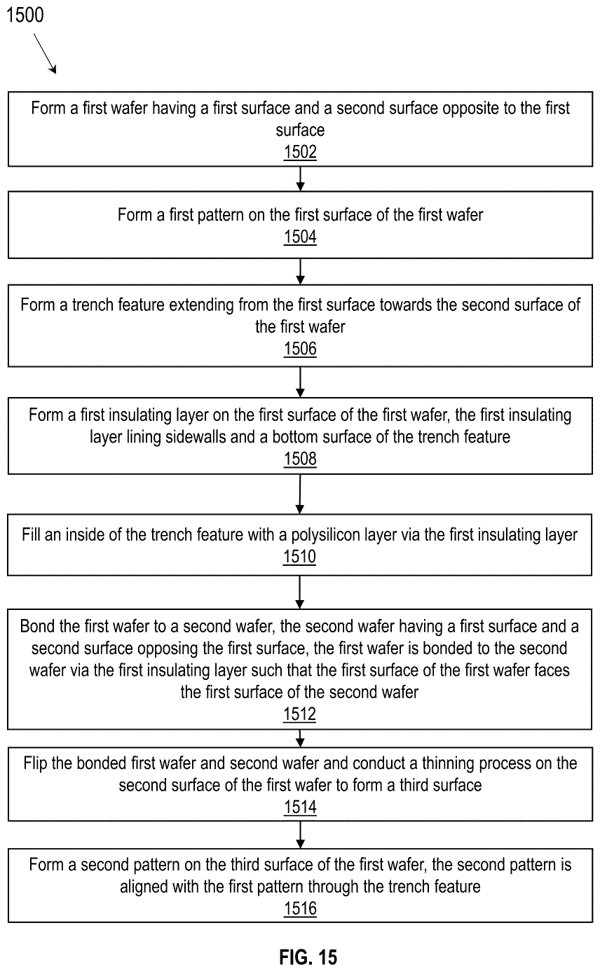

FIG. 15 is a flowchart 1500 depicting operational steps of a method for bonding SOI wafers with front and back-side patterns, according to an embodiment of the present disclosure.

The process starts at step 1502 by forming a first wafer having a first surface and a second surface opposing the first surface. The process continues at step 1504 by forming a first pattern on the first surface of the first wafer. In an embodiment, the first pattern includes a first plurality of doped regions including N-type sinker regions and P-type sinker regions. In an embodiment, the first plurality of doped regions further includes P-type buried layers and N-type buried layers aligned with a corresponding P-type or N-type sinker region.

At step 1506, a trench feature is formed extending from the first surface towards the second surface of the first wafer. The process continues at step 1508 by forming a first insulating layer on the first surface of the first wafer. The first insulating layer lines sidewalls and a bottom surface of the trench feature. The process continues at step 1510 by filling an inside of the trench feature with a polysilicon layer via the first insulating layer. The process continues at step 1512 by bonding the first wafer to a second wafer. The second wafer has a first surface and a second surface opposing the first surface, with the first wafer being bonded to the second wafer via the first insulating layer such that the first surface of the first wafer faces the first surface of the second wafer. The second wafer includes a second insulating layer formed on the first surface of the second wafer prior to bonding the first wafer to the second wafer. In an embodiment, bonding the first wafer to the second wafer is conducted using the first insulating layer and the second insulating layer. The process continues at step 1514 by flipping the bonded first wafer and second wafer and conducting a thinning process on the second surface of the first wafer to form a third surface.

Finally, at step 1516, a second pattern is formed on the third surface of the first wafer. The second pattern is aligned with the first pattern through the trench feature. In an embodiment, after thinning the second surface and prior to forming the second pattern, upper portions of the first insulating layer adjacent to the polysilicon layer positioned within the trench feature are selectively removed, with the removal forming a recess that defines an alignment mark within the trench feature.

In an embodiment, the second pattern includes a second plurality of doped regions including one or more of a well region positioned above and in alignment with a corresponding P-type or N-type buried layer.

In an embodiment, the second pattern further includes a transistor region formed by performing the steps of: depositing and patterning a hard mask layer on the second surface of the first wafer, the hard mask layer covering the well region and the first pattern, forming a third insulating layer above exposed portions of the second surface of the first wafer not covered by the hard mask layer, and removing the hard mask layer to expose the well region and the first pattern. In an embodiment, forming the transistor region further includes the steps of forming a gate oxide above the well region, forming a gate electrode above the gate oxide, oxidizing the gate electrode, forming a source region and a drain region on opposite sides of the gate electrode, and forming a metal contact to the source region, the gate electrode, the drain region, and the first pattern.

The previously described embodiments introduce a new level of integration in bonded SOI processing by utilizing both front and back sides of the device wafer to create patterned layers. Unlike traditional approaches, where an epitaxial (epi) layer is required to incorporate buried layers, embodiments of the present disclosure eliminate the need for epi deposition. Epi deposition may not only increase fabrication costs but also may introduce undesirable effects such as autodoping, defects, pattern washout, and non-optimum buried layer depths due to diffusion rate variations among different dopants. By eliminating the epi layer, embodiments of the present disclosure may eliminate these drawbacks, leading to a more precise and cost-effective process.

Furthermore, embodiments of the present disclosure may allow for independent customization of buried layers and sinkers, enabling precise control over diffusion depth into the silicon. This level of control may not be achievable in traditional epi-based processes, where diffusion rates vary depending on the dopant type. By leveraging wafer bonding and double-sided patterning, the proposed embodiments may provide a more versatile and reliable approach to buried layer integration, enhancing the overall performance, scalability, and manufacturability of bonded SOI wafers.

In the proposed embodiments, where no epitaxial (epi) layer is required, doping of sinker regions (e.g., first and second sinker regions 206, 306) can be performed from either the first side 101 to the second side 103 of device wafer 102, from the second side 103 to the first side 101, or from both sides simultaneously to meet in the middle. This approach may eliminate concerns related to epi autodoping while enabling greater control over the dopant diffusion profile. Doping sinker regions from both sides of device wafer 102 can create a lower-resistance conduction path, improving device performance. Additionally, the proposed embodiments may allow for a thicker device layer, which is particularly beneficial for high-voltage applications, where increased silicon thickness is needed to support higher breakdown voltages and improved reliability.

In contrast, in a standard bonded wafer process that includes an epi layer, the sinker region is typically diffused from the top surface downward to connect with the buried layer. While it is theoretically possible to pattern and dope the sinker before epi deposition, along with the buried layers, this approach is avoided because it exacerbates the issue of epi autodoping, leading to unwanted dopant redistribution and process variability. As a result, the conventional process requires careful control over diffusion depth and is limited by the constraints imposed by the epi layer. In the proposed embodiments, these limitations are avoided by eliminating the need for an epi layer, allowing for greater flexibility in sinker formation and improved process control.

The ability to integrate front-side and back-side patterns on bonded SOI wafers may allow for more complex device architectures, providing benefits such as improved electrical efficiency, better heat dissipation, and higher integration density. Additionally, this dual-sided processing approach is particularly beneficial for MEMS and sensor fabrication, where precise alignment between both sides of the wafer is critical.

### EXAMPLES

Example 1. A method of forming a semiconductor structure comprising:

forming a first wafer, the first wafer having a first surface and a second surface opposing the first surface;

forming a first pattern on the first surface of the first wafer;

forming a trench feature extending from the first surface towards the second surface of the first wafer;

forming a first insulating layer on the first surface of the first wafer, the first insulating layer lining sidewalls and a bottom surface of the trench feature;

filling an inside of the trench feature with a polysilicon layer via the first insulating layer;

bonding the first wafer to a second wafer, the second wafer having a first surface and a second surface opposing the first surface, wherein the first wafer is bonded to the second wafer via the first insulating layer such that the first surface of the first wafer faces the first surface of the second wafer;

flipping the bonded first wafer and second wafer;

conducting a thinning process on the second surface of the first wafer, the thinning process forming a third surface of the first wafer; and

forming a second pattern on the third surface of the first wafer, wherein the second pattern is aligned with the first pattern through the trench feature.

Example 2. The method according to Example 1, further comprising:

forming a second insulating layer on the first surface of the second wafer prior to bonding the first wafer to the second wafer, wherein bonding the first wafer to the second wafer is conducted using the first insulating layer and the second insulating layer.

Example 3. The method according to Example 1, further comprising:

selectively removing upper portions of the first insulating layer adjacent to the polysilicon layer positioned within the trench feature, wherein a recess formed by the removal of the first insulating layer defines an alignment mark.

Example 4. The method according to Example 1, wherein the first pattern includes a first plurality of doped regions.

Example 5. The method according to Example 4, wherein the first plurality of doped regions includes N-type and P-type sinker regions.

Example 6. The method according to Example 5, wherein the first plurality of doped regions further includes P-type and N-type buried layers aligned with a corresponding P-type or N-type sinker region.

Example 7. The method according to Example 1, wherein the second pattern includes a second plurality of doped regions.

Example 8. The method according to Example 7, wherein the second plurality of doped regions includes a well region, wherein the well region is positioned above and in alignment with a corresponding P-type or N-type buried layer.

Example 9. The method according to Example 8, further comprising:

depositing and patterning a hard mask layer on the second surface of the first wafer, the hard mask layer covering the well region and the first pattern;

forming a third insulating layer above exposed portions of the second surface of the first wafer not covered by the hard mask layer; and

removing the hard mask layer to expose the well region and the first pattern.

Example 10. The method according to any of the preceding Examples, further comprising:

forming a gate oxide above the well region;

forming a gate electrode above the gate oxide;

oxidizing the gate electrode;

forming a source region and a drain region on opposite sides of the gate electrode; and

forming a metal contact to the source region, the gate electrode, the drain region, and the first pattern.

Example 11. A method of forming a semiconductor structure comprising:

forming a first wafer having a first surface and a second surface opposite to the first surface;

forming a first pattern on the first surface of the first wafer;

forming one or more trench features extending from the first surface into the first wafer toward the second surface;

forming a first insulating layer on the first surface, wherein the first insulating layer lines sidewalls and a bottom surface of the one or more trench features;

filling an inside of the one or more trench features with a polysilicon layer via the first insulating layer;

bonding the first wafer to a second wafer, the second wafer having a first surface and a second surface opposing the first surface, wherein the first wafer is bonded to the second wafer via the first insulating layer such that the first surface of the first wafer faces the first surface of the second wafer;

bonding the first surface of the first wafer to a second wafer using the first insulating layer and a second insulating layer disposed on the second wafer;

flipping the bonded first wafer and second wafer;

conducting a thinning process on the first wafer from the second surface, wherein the thinning process forms a third surface of the first wafer and exposes uppermost portions of the one or more trench features, the exposed uppermost portions of the one or more trench features serving as alignment markers on the second surface; and

forming a second pattern on the third surface of the first wafer, wherein the second pattern is aligned with the first pattern using the alignment markers formed by the one or more trench features.

Example 12. The method according to Example 11, further comprising:

forming a second insulating layer on the first surface of the second wafer prior to bonding the first wafer to the second wafer, wherein bonding the first wafer to the second wafer is conducted using the first insulating layer and the second insulating layer; and

selectively removing upper portions of the first insulating layer adjacent to the polysilicon layer positioned within the one or more trench features, wherein a recess formed by the removal of the first insulating layer defines the alignment markers.

Example 13. The method according to Example 11, wherein the first pattern includes a first plurality of doped regions.

Example 14. The method according to Example 13, wherein the first plurality of doped regions includes N-type and P-type sinker regions.

Example 15. The method according to Example 14, wherein the first plurality of doped regions further includes P-type and N-type buried layers aligned with a corresponding P-type or N-type sinker region.

Example 16. The method according to Example 11, wherein the second pattern includes a second plurality of doped regions.

Example 17. The method according to Example 16, wherein the second plurality of doped regions includes a well region, wherein the well region is positioned above and in alignment with a corresponding P-type or N-type buried layer.

Example 18. The method according to Example 17, further comprising:

depositing and patterning a hard mask layer on the second surface of the first wafer, the hard mask layer covering the well region and the first pattern;

forming a third insulating layer above exposed portions of the second surface of the first wafer not covered by the hard mask layer; and

removing the hard mask layer to expose the well region and the first pattern.

Example 19. The method according to any of the preceding Examples, further comprising:

forming a gate oxide above the well region;

forming a gate electrode above the gate oxide;

oxidizing the gate electrode;

forming a source region and a drain region on opposite sides of the gate electrode; and

forming a metal contact to the source region, the gate electrode, the drain region, and the first pattern.

Example 20. A semiconductor structure comprising:

a first wafer having a first surface and a second surface opposite to the first surface; and

a second wafer bonded to the first surface of the first wafer, the first wafer comprising:
a first pattern on the first surface of the first wafer;
one or more trench features extending from the first surface into the first wafer towards the second surface;
a first insulating layer positioned above the first surface, the first insulating layer and lining sidewalls and a bottom surface of the one or more trench features, wherein the second wafer is bonded to the first surface of the first wafer via the first insulating layer and a second insulating layer disposed on a surface of the second layer;
a polysilicon layer positioned within the one or more trench features above the first insulating layer, wherein uppermost portions of the polysilicon layer within the one or more trench features serve as alignment markers on the second surface; and
a second wafer bonded to the first surface of the first wafer via the first

insulating layer and a second insulating layer on the second wafer; and

a second pattern on the second surface of the first wafer, wherein the second pattern is aligned with the first pattern using the alignment markers.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Spatially relative terms, such as “inner,” “outer,” “beneath,” “below,” “lower,” “above,” “upper,” “top,” “bottom,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90 degrees or at other orientations) and the spatially relative descriptors used herein interpreted accordingly.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of forming a semiconductor structure comprising:
forming a first wafer, the first wafer having a first surface and a second surface opposing the first surface;
forming a first pattern on the first surface of the first wafer;
forming a trench feature extending from the first surface towards the second surface of the first wafer;
forming a first insulating layer on the first surface of the first wafer, the first insulating layer lining sidewalls and a bottom surface of the trench feature;
filling an inside of the trench feature with a polysilicon layer via the first insulating layer;
bonding the first wafer to a second wafer, the second wafer having a first surface and a second surface opposing the first surface, wherein the first wafer is bonded to the second wafer via the first insulating layer such that the first surface of the first wafer faces the first surface of the second wafer;
flipping the bonded first wafer and second wafer;
conducting a thinning process on the second surface of the first wafer, the thinning process forming a third surface of the first wafer; and
forming a second pattern on the third surface of the first wafer, wherein the second pattern is aligned with the first pattern through the trench feature.

2. The method according to claim 1, further comprising:
forming a second insulating layer on the first surface of the second wafer prior to bonding the first wafer to the second wafer, wherein bonding the first wafer to the second wafer is conducted using the first insulating layer and the second insulating layer.

3. The method according to claim 1, further comprising:
selectively removing upper portions of the first insulating layer adjacent to the polysilicon layer positioned within the trench feature, wherein a recess formed by the removal of the first insulating layer defines an alignment mark.

4. The method according to claim 1, wherein the first pattern includes a first plurality of doped regions.

5. The method according to claim 4, wherein the first plurality of doped regions includes N-type and P-type sinker regions.

6. The method according to claim 5, wherein the first plurality of doped regions further includes P-type and N-type buried layers aligned with a corresponding P-type or N-type sinker region.

7. The method according to claim 1, wherein the second pattern includes a second plurality of doped regions.

8. The method according to claim 7, wherein the second plurality of doped regions includes a well region, wherein the well region is positioned above and in alignment with a corresponding P-type or N-type buried layer.

9. The method according to claim 8, further comprising:
depositing and patterning a hard mask layer on the second surface of the first wafer, the hard mask layer covering the well region and the first pattern;
forming a third insulating layer above exposed portions of the second surface of the first wafer not covered by the hard mask layer; and
removing the hard mask layer to expose the well region and the first pattern.

10. The method according to claim 9, further comprising:
forming a gate oxide above the well region;
forming a gate electrode above the gate oxide;
oxidizing the gate electrode;
forming a source region and a drain region on opposite sides of the gate electrode; and
forming a metal contact to the source region, the gate electrode, the drain region, and the first pattern.

11. A method of forming a semiconductor structure comprising:
forming a first wafer having a first surface and a second surface opposite to the first surface;
forming a first pattern on the first surface of the first wafer;
forming one or more trench features extending from the first surface into the first wafer toward the second surface;
forming a first insulating layer on the first surface, wherein the first insulating layer lines sidewalls and a bottom surface of the one or more trench features;
filling an inside of the one or more trench features with a polysilicon layer via the first insulating layer;
bonding the first wafer to a second wafer, the second wafer having a first surface and a second surface opposing the first surface, wherein the first wafer is bonded to the second wafer via the first insulating layer such that the first surface of the first wafer faces the first surface of the second wafer;
flipping the bonded first wafer and second wafer;
conducting a thinning process on the first wafer from the second surface, wherein the thinning process forms a third surface of the first wafer and exposes uppermost portions of the one or more trench features, the exposed uppermost portions of the one or more trench features serving as alignment markers on the second surface; and
forming a second pattern on the third surface of the first wafer, wherein the second pattern is aligned with the first pattern using the alignment markers formed by the one or more trench features.

12. The method according to claim 11, further comprising:
forming a second insulating layer on the first surface of the second wafer prior to bonding the first wafer to the second wafer, wherein bonding the first wafer to the second wafer is conducted using the first insulating layer and the second insulating layer; and
selectively removing upper portions of the first insulating layer adjacent to the polysilicon layer positioned within the one or more trench features, wherein a recess formed by the removal of the first insulating layer defines the alignment markers.

13. The method according to claim 11, wherein the first pattern includes a first plurality of doped regions.

14. The method according to claim 13, wherein the first plurality of doped regions includes N-type and P-type sinker regions.

15. The method according to claim 14, wherein the first plurality of doped regions further includes P-type and N-type buried layers aligned with a corresponding P-type or N-type sinker region.

16. The method according to claim 11, wherein the second pattern includes a second plurality of doped regions.

17. The method according to claim 16, wherein the second plurality of doped regions includes a well region, wherein the well region is positioned above and in alignment with a corresponding P-type or N-type buried layer.

18. The method according to claim 17, further comprising:
depositing and patterning a hard mask layer on the second surface of the first wafer, the hard mask layer covering the well region and the first pattern;
forming a third insulating layer above exposed portions of the second surface of the first wafer not covered by the hard mask layer; and
removing the hard mask layer to expose the well region and the first pattern.

19. The method according to claim 18, further comprising:
forming a gate oxide above the well region;
forming a gate electrode above the gate oxide;
oxidizing the gate electrode;
forming a source region and a drain region on opposite sides of the gate electrode; and
forming a metal contact to the source region, the gate electrode, the drain region, and the first pattern.

20. A semiconductor structure comprising:
a first wafer having a first surface and a second surface opposite to the first surface; and
a second wafer bonded to the first surface of the first wafer, the first wafer comprising:
a first pattern on the first surface of the first wafer;
one or more trench features extending from the first surface into the first wafer towards the second surface;
a first insulating layer positioned above the first surface, the first insulating layer lining sidewalls and a bottom surface of the one or more trench features, wherein the second wafer is bonded to the first surface of the first wafer via the first insulating layer and a second insulating layer disposed on a surface of the second wafer;
a polysilicon layer positioned within the one or more trench features above the first insulating layer, wherein uppermost portions of the polysilicon layer within the one or more trench features serve as alignment markers on the second surface; and
a second pattern on the second surface of the first wafer, wherein the second pattern is aligned with the first pattern using the alignment markers.
